(19) United States
(12) Patent Application Publication
(10) Pub. No.: US 2020/0006274 A1
(43) Pub. Date: Jan. 2, 2020

(54) SEMICONDUCTOR PACKAGE AND MANUFACTURING METHOD THEREOF

(71) Applicant: Powertech Technology Inc., Hsinchu County (TW)

(72) Inventors: Chia-Wei Chiang, Hsinchu County (TW); Li-Chih Fang, Hsinchu County (TW); Wen-Jeng Fan, Hsinchu County (TW)

(73) Assignee: Powertech Technology Inc., Hsinchu County (TW)

(21) Appl. No.: 16/022,707

(22) Filed: Jun. 29, 2018

(51) Int. Cl. H01L 23/00; H01L 23/31; H01L 25/10; H01L 21/56; H01L 25/00; H01L 21/683; H01L 23/48

(52) U.S. Cl. CPC H01L 24/24; H01L 21/31053; H01L 23/3128; H01L 25/105; H01L 24/19; H01L 21/568; H01L 25/50; H01L 21/6838; H01L 23/481; H01L 2225/1023; H01L 2225/1041; H01L 2225/1047; H01L 2224/221; H01L 2224/24146; H01L 2221/68359; H01L 24/20

(57) ABSTRACT

A semiconductor package includes a semiconductor die, a first redistribution structure, a conductive structure, and an insulating encapsulant. The first redistribution structure includes a dielectric protrusion. The first redistribution structure includes a die attach region and a peripheral region surrounding the die attach region. The semiconductor die is disposed on the first redistribution structure within the die attach region. The dielectric protrusion is disposed in the peripheral region and extends in a thickness direction of the semiconductor die. The conductive structure is disposed on the first redistribution structure within the in the peripheral region and encapsulates the semiconductor dielectric protrusion. The conductive structure is electrically coupled to the first redistribution structure and the semiconductor die. The insulator is disposed on the first redistribution structure and encapsulates the semiconductor die and the conductive structure.

### BACKGROUND OF THE INVENTION

### 1. Field of the Invention

The disclosure generally relates to a semiconductor package and a manufacturing method thereof, and, in particular, to a semiconductor package having a conductive structure and a redistribution structure with a dielectric protrusion, and a manufacturing method thereof.

### 2. Description of Related Art

Electronic products that are lighter, slimmer, shorter, and smaller than their previous generation counterparts are highly sought on the market. Therefore, extensive research is performed to find new technologies for semiconductor packaging that help to reduce the volume and the weight of existing devices. 3D stacking technologies such as package-on-package have been developed to meet the requirements of higher packaging densities.

### SUMMARY OF THE INVENTION

The disclosure provides a semiconductor package able to vertically integrate devices with increased structural resistance and a manufacturing method thereof.

The disclosure provides a semiconductor package including a semiconductor die, a first redistribution structure, a conductive structure, and an insulating encapsulant. The first redistribution structure includes a dielectric protrusion. The first redistribution structure comprises a die attach region and a peripheral region surrounding the die attach region. The semiconductor die is disposed on the first redistribution structure within the die attach region. The dielectric protrusion is disposed in the peripheral region and extends in a thickness direction of the semiconductor die. The conductive structure is disposed on the first redistribution structure within the in the peripheral region and encapsulates the semiconductor dielectric protrusion. The conductive structure is electrically coupled to the first redistribution structure and the semiconductor die. The insulating encapsulant is disposed on the first redistribution structure and encapsulates the semiconductor die and the conductive structure.

The disclosure provides a manufacturing method of a semiconductor package. The method includes at least the following steps. A first redistribution structure is formed. The first redistribution structure includes a die attach region and a peripheral region surrounding the die attach region. The first redistribution structure includes a dielectric protrusion formed in the peripheral region and extending along a thickness direction of the first redistribution structure. A conductive structure is formed on the dielectric protrusion to encapsulate the dielectric protrusion. The dielectric protrusion extends in a height direction of the conductive structure. The semiconductor die is disposed on the first redistribution structure within the die attach region to electrically couple to the first redistribution structure and the conductive structure. An insulating encapsulant is formed on the first redistribution structure to encapsulate the conductive structure and the semiconductor die.

Based on the above, the semiconductor package is formed with a peripheral design suitable for dual-side vertical integration. Vertical electrical connection within the semiconductor package is provided by the conductive structure embedded in the insulating encapsulant. The conductive structure may provide electrical connection and, at the same time, mechanical support within the semiconductor package. Since the dielectric protrusion is encapsulated by the conductive structure, additional mechanical support can be provided to the conductive structure.

To make the aforementioned more comprehensible, several embodiments accompanied with drawings are described in detail as follows.

### BRIEF DESCRIPTION OF THE DRAWINGS

The accompanying drawings are included to provide further understanding of the disclosure, and are incorporated in and constitute a part of this specification. The drawings illustrate exemplary embodiments of the disclosure and, together with the description, serve to explain the principles of the disclosure.

FIG. 1A to FIG. 1Q are schematic cross-sectional views illustrating an application of a semiconductor package produced by a manufacturing method according to some embodiments of the disclosure.

FIG. 2A to FIG. 2H are schematic cross-sectional views illustrating an application of a semiconductor package produced by a manufacturing method according to some embodiments of the disclosure.

### DESCRIPTION OF THE EMBODIMENTS

Reference will now be made in detail to some embodiments of the present disclosure, examples of which are illustrated in the accompanying drawings. Wherever possible, the same reference numbers are used in the drawings and the description to refer to the same or like parts.

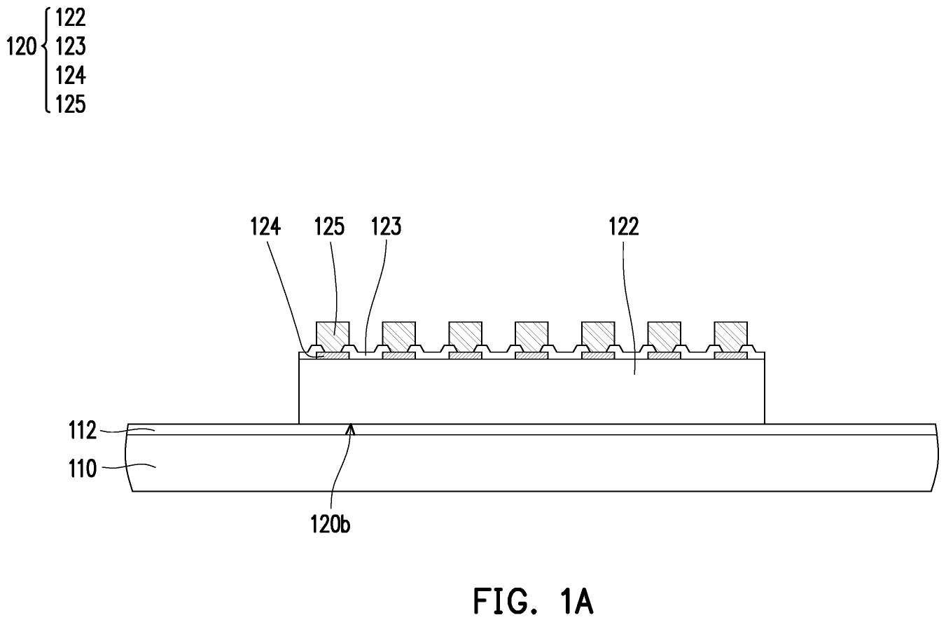

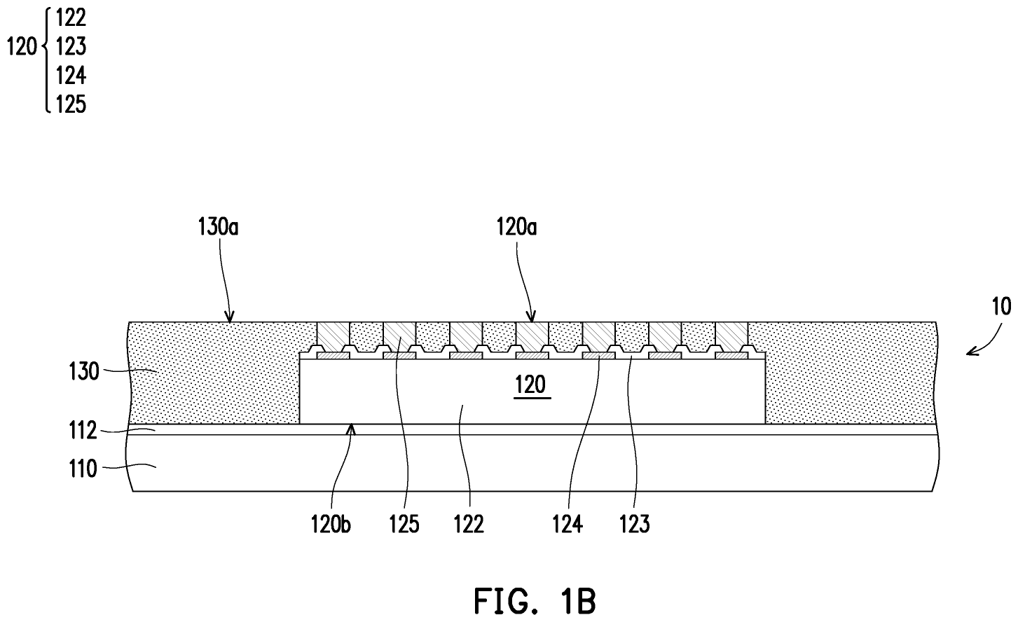

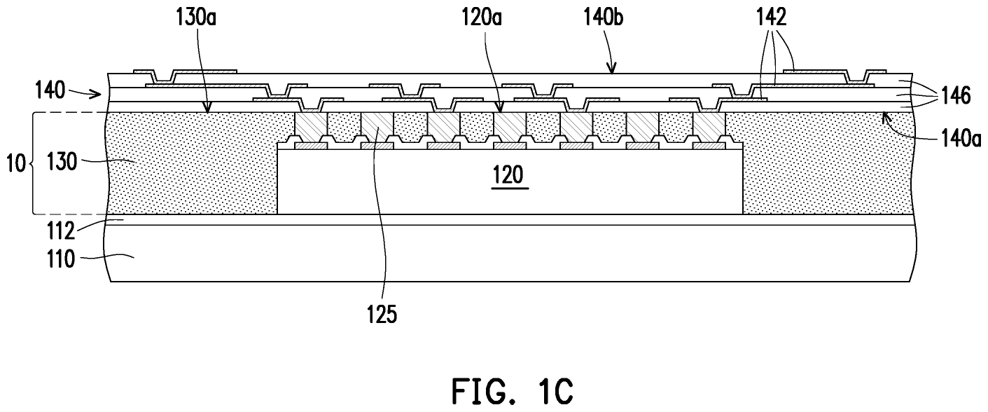

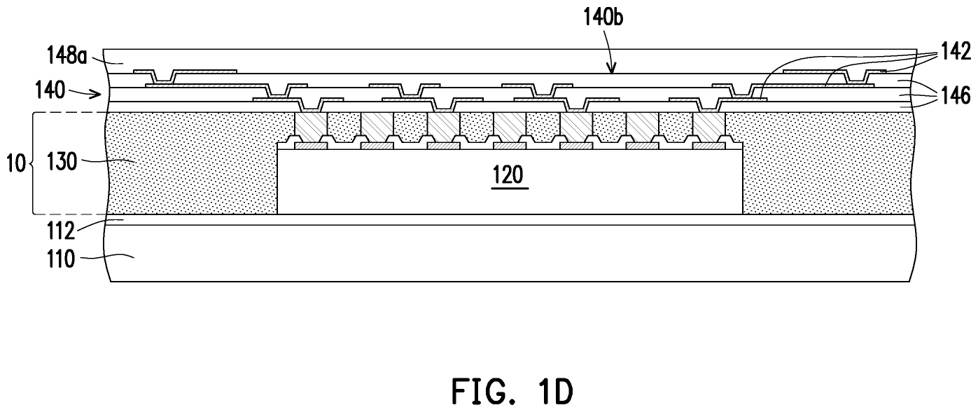

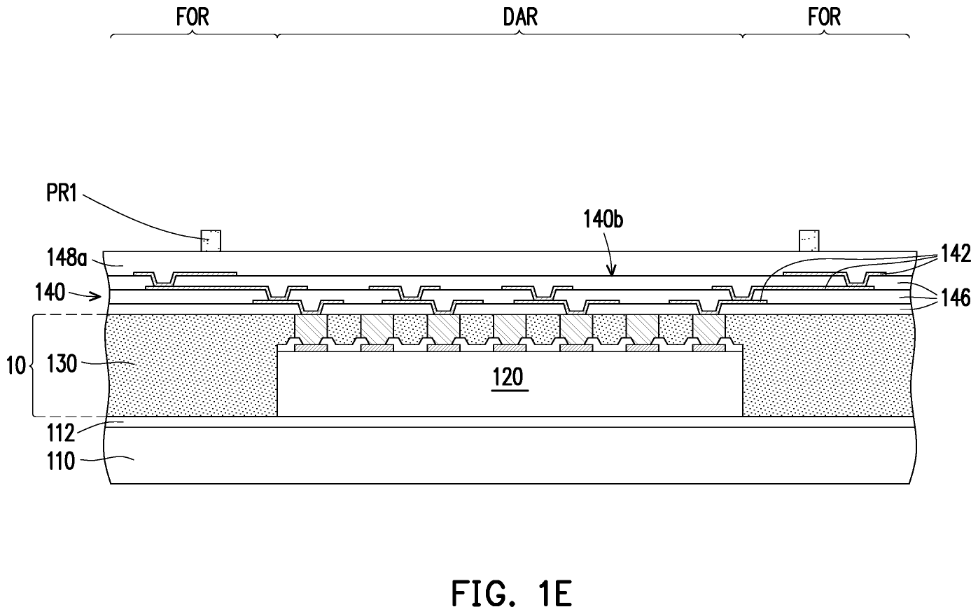

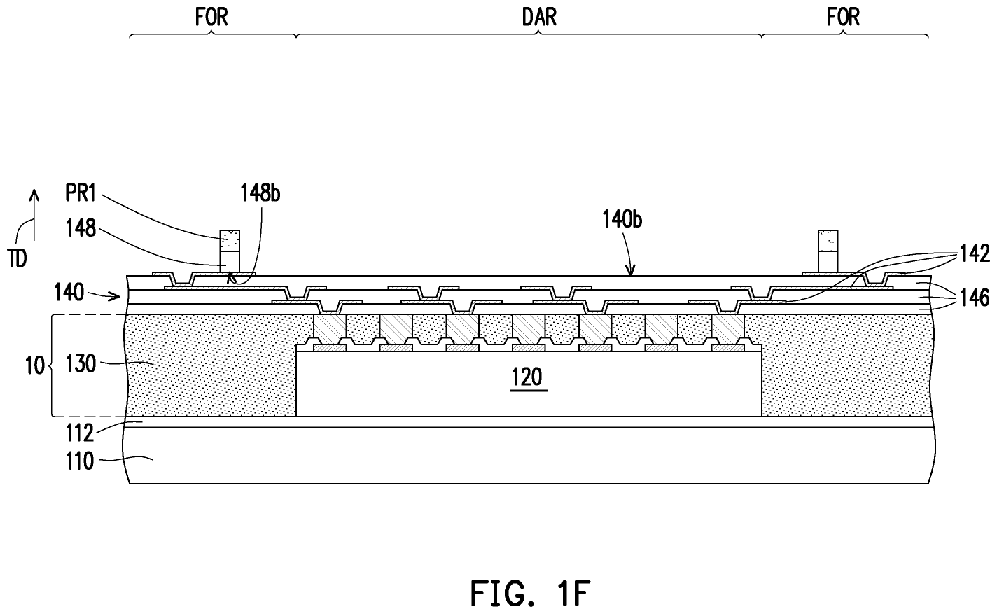

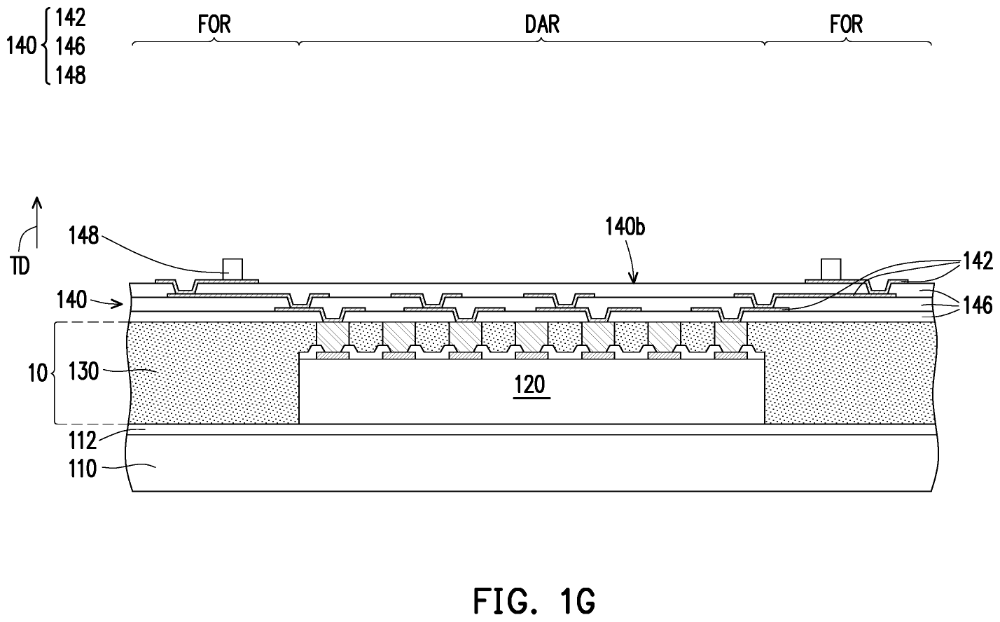

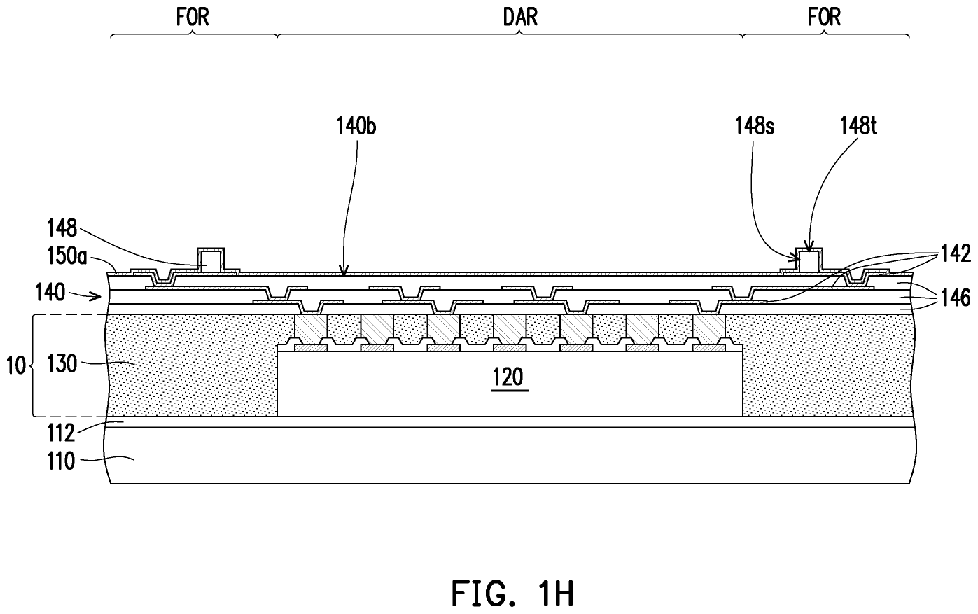

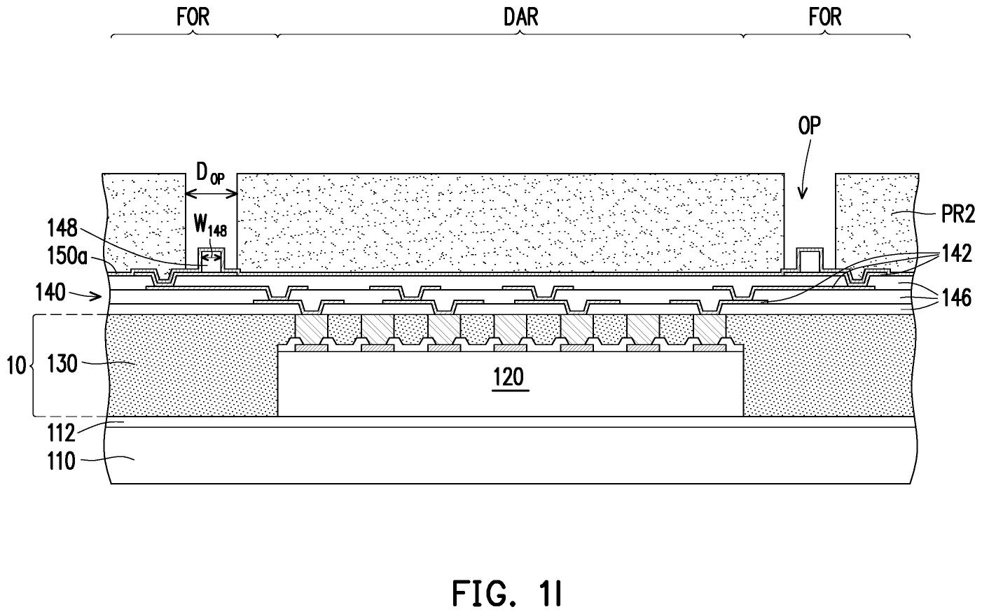

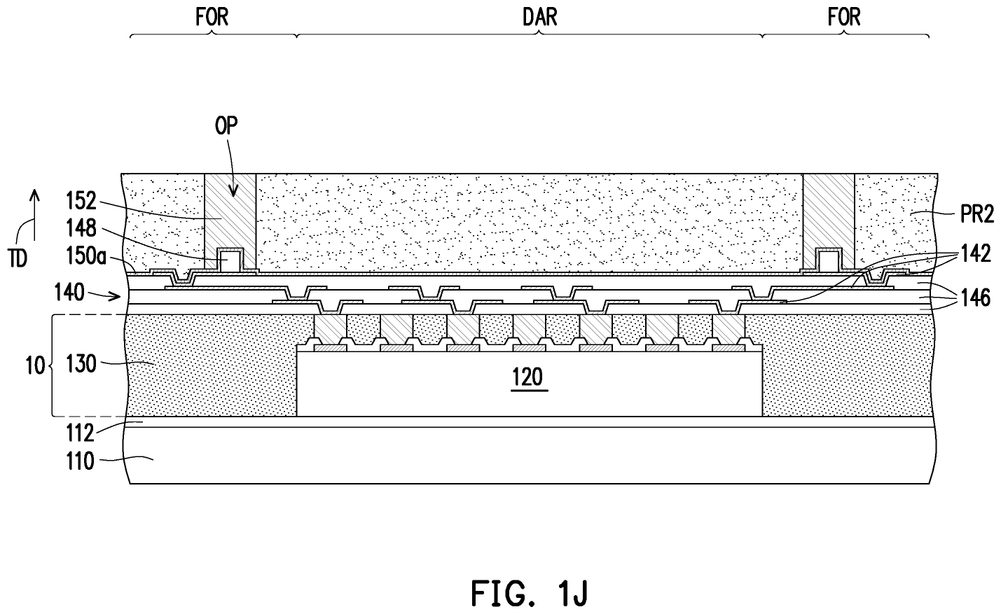

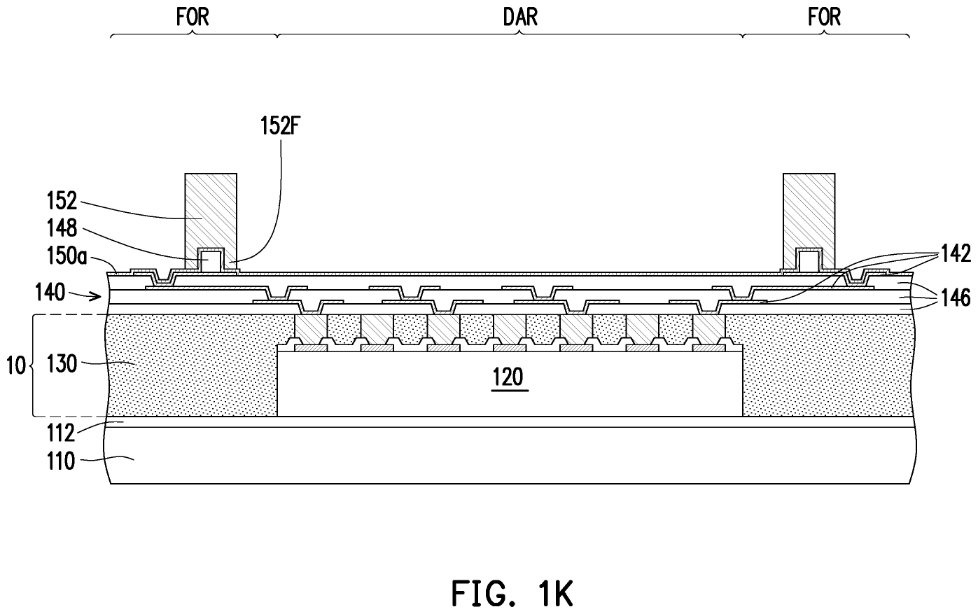

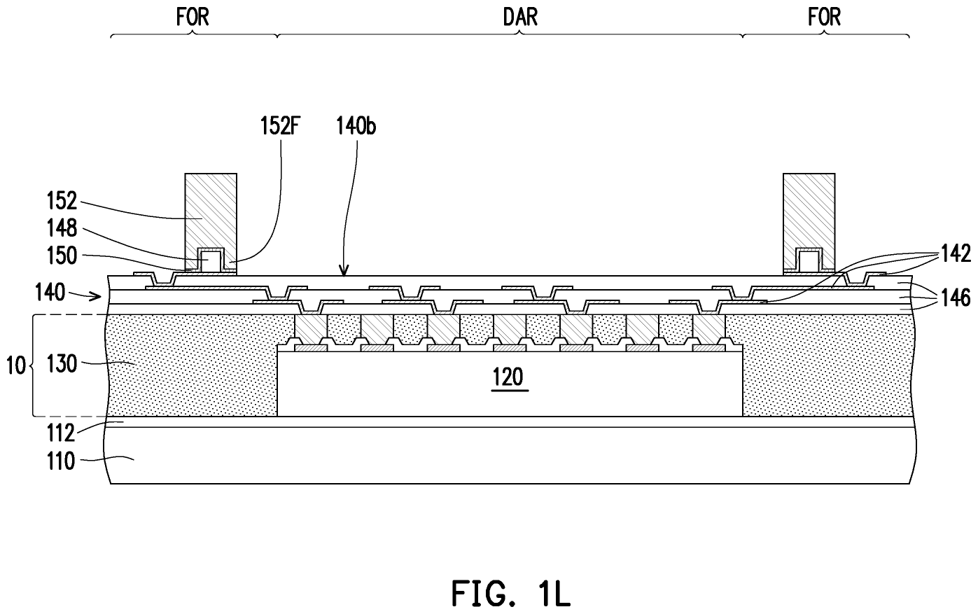

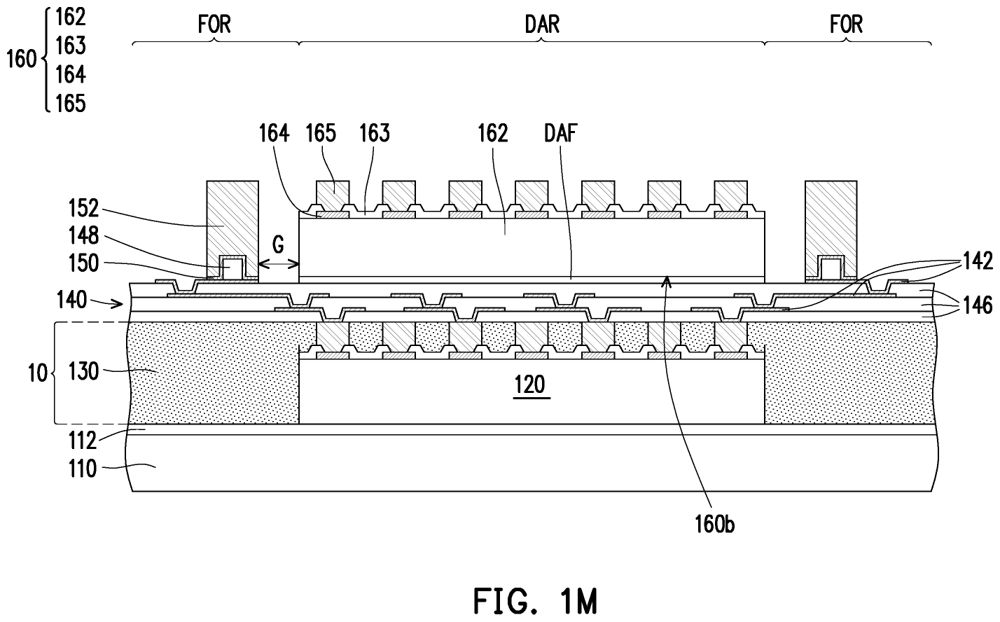

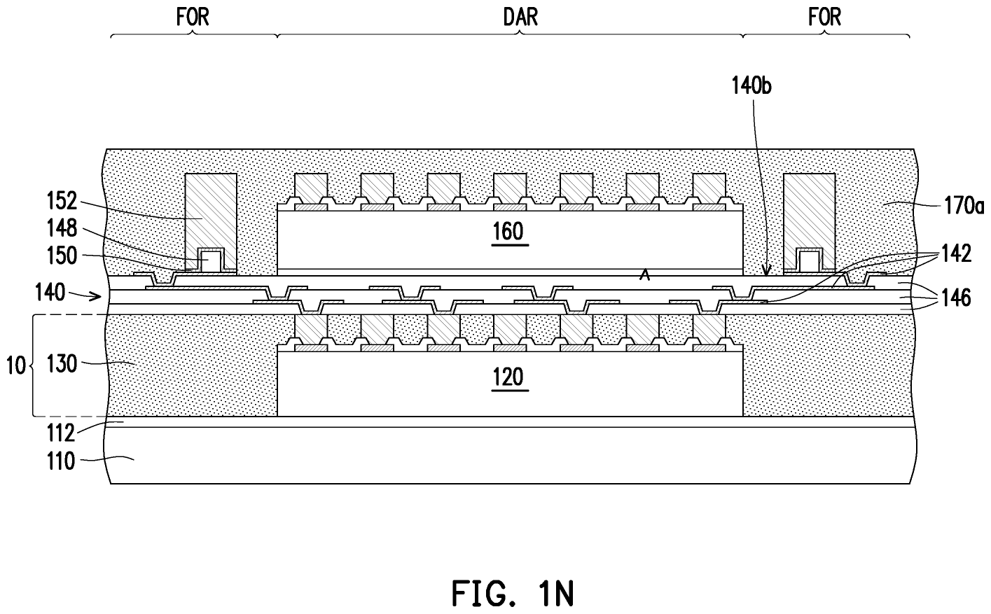

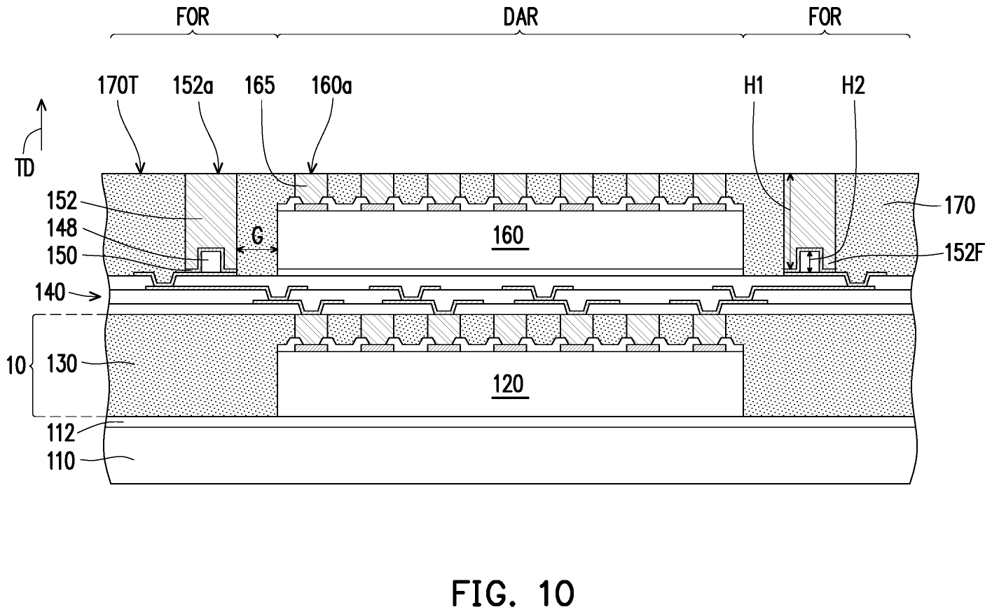

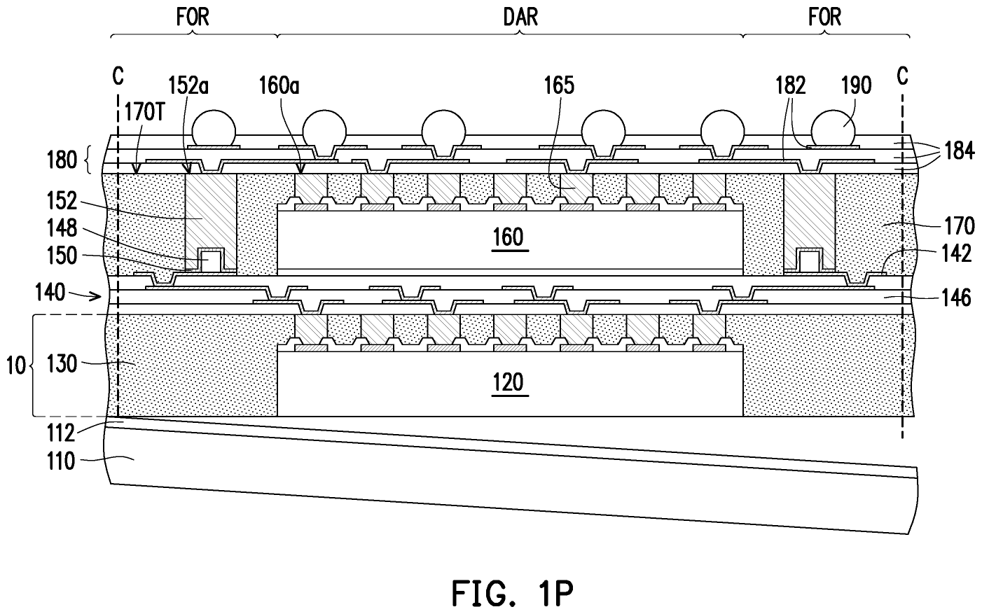

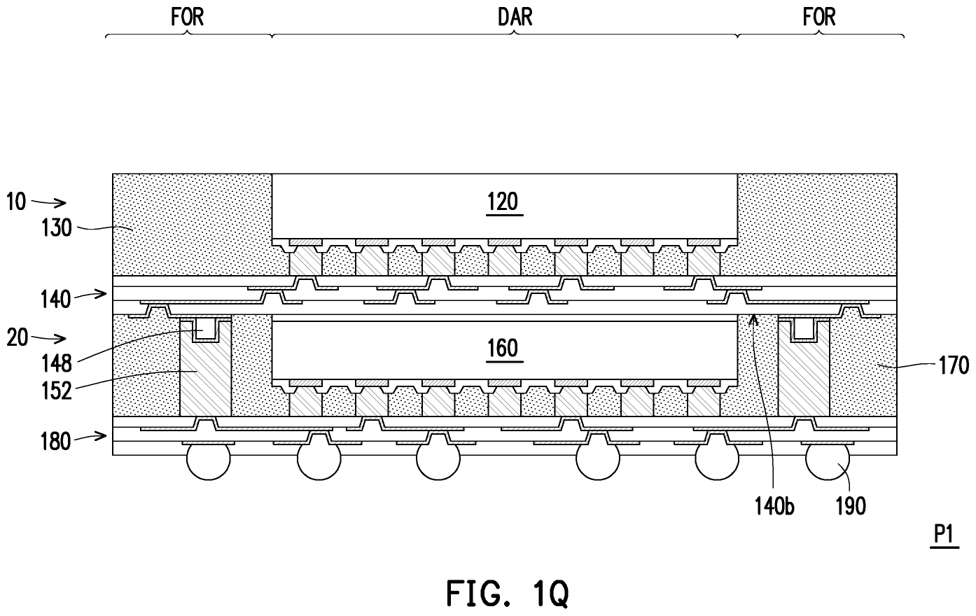

FIG. 1A to FIG. 1Q are schematic cross-sectional views illustrating an application of a manufacturing method of a semiconductor package 20 according to some embodiments of the disclosure. As shown in FIG. 1A, a semiconductor chip 120 may be disposed on the temporary carrier 110 using a pick and place technique. The temporary carrier 110 may be a glass substrate, a metal plate, a plastic supporting board or the like. Other suitable substrate materials may be adapted as the temporary carrier 110 as long as the materials are able to withstand the subsequent processes while forming the semiconductor package 20. A release layer 112 may be formed on the temporary carrier 110 to enhance the adhesion between the temporary carrier 110 and the semiconductor device 10. The release layer 112 may include a layer of light-to-heat-conversion (LTHC) release coating, epoxy resins, inorganic materials, organic polymeric materials, or other suitable adhesive materials. The semiconductor chip 120 may be a memory chip (e.g., RAM, DRAM, or SDRAM), a logic chip, or other suitable chips. The semiconductor chip 120 may include a semiconductor substrate 122, a plurality of connection pads 124, a passivation layer 123 partially covering the connection pads 124, and a plurality of conductive bumps 125 disposed on and electrically connected to the connection pads 124 exposed by the passivation layer 123. The semiconductor chip 120 may have a rear surface 120b in contact with the release layer 112. In some embodiments, the semiconductor substrate 122 may be a silicon substrate including active components (e.g., transistors or the like) and, optionally, a passive component (e.g., resistor, capacitor, inductor, or the like) formed therein. The connection pads 124 may be aluminium pads, copper pads, or other suitable metal pads. The conductive bumps 125 may be copper, aluminium, or other suitable conductive materials.

As shown in FIG. 1B, an insulator 130 is disposed on the temporary carrier 110 and encapsulates the semiconductor chip 120 to form the semiconductor device 10. An insulating material (not shown) is disposed on the temporary carrier 110 to completely cover the semiconductor chip 120. The insulating material may include polymers, epoxy resins, molding compound, or other suitable resins. A thickness of the insulating material is subsequently planarized until at least the top surfaces 120a of the conductive bumps 125 are exposed to form an insulator 130. A mechanical grinding process, a chemical mechanical polishing (CMP) process, or any other suitable process may be used in the planarization process. After the planarization process, the top surfaces 120a are substantially coplanar with a top surface 130a of the insulator 130. The steps of the method may produce a plurality of semiconductor packages 20 simultaneously. A singulation step may be performed as needed.

Referring to FIG. 1C, a first redistribution structure 140 is formed over the semiconductor device 10. The first redistribution structure 140 has a first surface 140a and a second surface 140b opposite to the first surface 140a. The first surface 140a may be in direct contact with the top surface 130a of the insulator 130 and the top surfaces 120a of the semiconductor chip 120. The first redistribution structure 140 may include at least one patterned conductive layer 142 and at least one patterned dielectric layer 146. The patterned dielectric layer 146 may be made of inorganic or organic dielectric materials such as silicon oxide, polybenzoxazole (PBO), polyimide (PI), benzocyclobutene (BCB), or the like. In some embodiments, a plurality of patterned dielectric layers 146 and a plurality of patterned conductive layers 142 are stacked alternately.

To form a patterned dielectric layer 146, a layer of dielectric material may be formed over the semiconductor device 10 and portions of the layer of the dielectric material may be removed using lithography and etching process, or other suitable methods to form a plurality of openings exposing portions of the conductive material underneath. The conductive material underneath may be a surface of the bumps 125 of the semiconductor chip 120 or a portion of a patterned conductive layers 142. A seed layer (not illustrated) may be conformally formed over the patterned dielectric layer 146 using a deposition process, or other suitable methods. A photoresist layer (not illustrated) having openings may be formed on the seed layer. A conductive material (e.g., copper, copper alloy, aluminum, aluminum alloy, or combinations thereof) may be formed on the seed layer in the openings of the photoresist layer using deposition, plating, or other suitable process. The photoresist layer may be removed. The seed layer formed underneath the photoresist layer may be removed through etching or other suitable removal process. The remaining portions of the seed layer and the conductive material may form the patterned conductive layer 142. The abovementioned steps may be performed multiple times as required by the circuit design.

As shown in FIG. 1D, the first redistribution structure 140 may further include a dielectric protrusion 148. After forming the top patterned conductive layer 142, a dielectric layer 148a is formed on the second surface 140b to cover the top patterned conductive layer 142 and the top patterned dielectric layer 146. The dielectric layer 148a may be formed through spin coating, deposition, lamination, or other suitable techniques. The material for the dielectric layer 148a may be similar to the patterned dielectric layer 146.

As shown in FIG. 1E, the first redistribution structure 140 may include a die attach region DAR and a peripheral region FOR. A first patterned photoresist PR1 may be formed on the dielectric layer 148a disposed above the top patterned conductive layer 142 in the peripheral region FOR. The first patterned photoresist PR1 can be a positive photoresist or a negative photoresist. The first patterned photoresist PR1 may be formed on the layer of dielectric material 148a through a sequence of deposition, exposure, development steps. However, other suitable processes may be followed in alternative embodiments.

Referring to FIGS. 1F and 1G, a portion of the layer of dielectric material 148a may be removed to form the dielectric protrusion 148. The first patterned photoresist PR1 is used as a mask during the removing step. The portion of the dielectric layer 148a not covered by the first patterned photoresist PR1 may be removed to expose the second surface 140b of the first redistribution structure 140. Therefore, the dielectric protrusion 148 reproduces the pattern of the first patterned photoresist PR1. The first patterned photoresist PR1 may be removed using a stripping process, or other suitable techniques. The dielectric protrusion 148 extends in a perpendicular direction TD from the first redistribution structure 140. A bottom surface 148b of the dielectric protrusion 148 may be in direct contact with a portion of the top patterned conductive layer 142. While only two dielectric protrusions 148 are shown in FIG. 1G, the number of dielectric protrusions 148 is not limited thereto. One or more dielectric protrusions 148 can be formed on the semiconductor package 20 as required. In some alternative embodiments, the dielectric protrusion 148 may be formed using other suitable process, such as lamination or the like.

Referring to FIG. 1H, a seed layer 150a may be conformally formed over the exposed second surface 140b (including the top patterned dielectric layer 142 and the top patterned conductive layer 146) of the first redistribution structure 140 and the top surface 148t and the side surface 148s of the dielectric protrusion 148. The seed layer 150a may be formed using deposition, electroless plating, sputtering, or other suitable process. The seed layer 150a may be a single conductive layer or a composite layer including several sub-layers of different materials (e.g., Ti/Cu layer). A barrier layer (not shown) may be formed before the seed layer 150a to prevent diffusion of the seed layer material to the adjacent elements in the semiconductor package 20.

Referring to FIG. 1I, a second patterned photoresist PR2 may be formed on the seed layer 150a. The second patterned photoresist PR2 may be formed in the same way as the first patterned photoresist PR1, therefore, description thereof is omitted for brevity. The second patterned photoresist PR2 may have openings OP exposing the dielectric protrusion 148 covered by the seed layer 150a. A width (e.g., diameter) D_{OP} of an opening OP of the second patterned photoresist PR2 is greater than a width W₁₄₈ of a corresponding dielectric protrusion 148. The opening OP may be circular, rectangular, square, or other polygonal shape. In some embodiments, each opening OP may have one or more dielectric protrusions 148.

Referring to FIG. 1J and FIG. 1K, a conductive structure 152 may be formed by filling the opening OP with a conductive material using electroplating, electroless plating, or other suitable deposition process. After forming the conductive structure 152, the second patterned photoresist PR2 is removed. As shown in FIG. 1K, The conductive structure 152 may encapsulate the dielectric protrusion 148 and extend along the thickness direction TD. The dielectric protrusion 148 is embedded within the conductive structure 152. A footing portion 152F of the conductive structure 152 includes a recess having a shape complementary to the shape of dielectric protrusion 148 coated with the seed material layer 150a embedded therein. The footing portion 152F of the conductive structure 152 may be electrically connected to the patterned conductive layer 142 of the first redistribution structure 140.

In some alternative embodiments, the conductive structure 152 may be formed by stencil/screen printing using patterned screen instead of the second patterned photoresist PR2. However, other suitable techniques can be utilized to form the conductive structure 152. Whilst in the drawings of the present disclosure two conductive structures 152 are shown, the number of conductive structures 152 is not to be construed as a limitation of the disclosure. In some embodiments, fewer or more conductive structures 152 can be part of the semiconductor package 20.

Upon removal of the second patterned photoresist PR2, a portion of the seed layer 150a is exposed again. With reference to FIG. 1L, the exposed portion of the seed layer 150a may be removed using a selective etching process, or other suitable process to form a seed layer 150 disposed between the dielectric protrusion 148 and the conductive structure 152. The lateral surface of the footing portion 152F may be substantially aligned with the lateral surface of the seed layer 150. The seed layer 150 may be in physical contact with the top patterned conductive layer 142. The conductive structure 152 is electrically coupled to the semiconductor device 10 through the first redistribution structure 140. After removing a portion of the seed layer 150a, the second surface 140b of the first redistribution structure 140 other than the portion covered by the conductive structure 152 may be exposed again.

Referring to FIG. 1M, a semiconductor die 160 may be disposed on the die attach region DAR of the first redistribution structure 140. In some embodiments, a horizontal gap G may be formed between the sidewall of the semiconductor die 160 and the sidewall of the conductive structures 152. The semiconductor die 160 may be a logic chip, a calculating chip, an ASIC (Application Specific Integrated Circuit) or other suitable semiconductor device. The semiconductor die 160 includes a semiconductor substrate 162, a plurality of connection pads 164, a passivation layer 163 partially covering the connection pads 164, and a plurality of conductive bumps 165 disposed on the connection pads 164 exposed by the passivation layer 163 to electrically connect the semiconductor die 160 to other components. In some embodiments, the semiconductor substrate 162 may be a silicon substrate including active components (e.g., transistors or the like) and optionally passive components (e.g., resistors, capacitors, inductors, or the like) formed therein. The connection pads 164 may include aluminium pads, copper pads, or other suitable metal pads. The conductive bumps 165 may include copper, aluminium, or other suitable conductive materials.

The semiconductor die 160 is disposed to have a rear surface 160b of the semiconductor die 160 facing towards the first redistribution structure 140. In some embodiments, the semiconductor die 160 is provided with a die attach layer DAF disposed between the semiconductor die 160 and the first redistribution structure 140 to reduce the shift of the semiconductor die 160. In some alternative embodiments, the semiconductor die 160 may be disposed in a face-down configuration using a flip-chip technique such that the conductive bumps 165 of the semiconductor die 160 are in direct contact with the patterned conductive layer 142 of the first redistribution structure 140.

Referring to FIG. 1N and FIG. 1O, an encapsulation material 170a may be formed over the second surface 140b of the first redistribution structure 140 to cover the semiconductor die 160 and the conductive structure 152 using a molding process. The gap G may be filled by the encapsulation material 170a. The encapsulation material 170a may include polymers, epoxy resins, molding compound, or other suitable insulating materials. A thickness of the encapsulation material 170a is reduced until at least a portion of the conductive structure 152 and at least a portion of the conductive bumps 165 are exposed to form an insulating encapsulant 170. The encapsulation material 170a is planarized using a mechanical grinding process, a CMP process, or any other suitable processes.

The top surface 160a of the conductive bumps 165 is substantially coplanar with the top surface 170T of the insulating encapsulant 170 and the top surface 152a of the conductive structure 152. The conductive structure 152 has a maximum height H1 measured from the surface of the footing portion 152F facing toward the first redistribution structure 140 to the top surface 152a. In some embodiments, a ratio between the maximum height H1 of the conductive structure 152 and a height H2 of the dielectric protrusion 148 measured ranges from 5 to 50.

Referring to FIG. 1P, a second redistribution structure 180 may be formed over the top surface 170T of the insulating encapsulant 170, the top surface 152a of the conductive structure 152 and the top surfaces 160a. The second redistribution structure 180 may include at least one patterned conductive layer 182 and at least one patterned dielectric layer 184. A fabrication process of the second redistribution structure 180 may be similar to that of the first redistribution structure 140, and a detailed description thereof is omitted for brevity. In some embodiments, after forming the second redistribution structure 180, the top patterned dielectric layer 184 may have openings exposing at least the portion of the top patterned conductive layer 182. In some embodiments, the top layer of the patterned dielectric layer 184 may include solder sensitive material to protect the patterned conductive layer 182 during a ball mounting process. The solder sensitive material may be an under-ball metallurgy (UBM) pads.

In some embodiments, after forming the second redistribution structure 180, the second redistribution structure 180 is electrically connected to the semiconductor die 160 and the conductive structure 152. The patterned conductive layer 182 is physically connected to the conductive bumps 165 of the semiconductor die 160 and the conductive structure 152. The semiconductor die 160 is electrically coupled to the semiconductor chip 120 through the first redistribution structure 140, the conductive structure 152 and the second redistribution structure 180. In some embodiments, the top surfaces 160a of the semiconductor die 160 face towards the second redistribution structure 180 such that the second redistribution structure 180 may be referred to as a front side redistribution layer (RDL), and the first redistribution structure 140 may be referred to as a backside RDL given the placements in the structure.

After forming the second redistribution structure 180, a plurality of conductive terminals 190 may be formed on the second redistribution structure 180 opposite to the insulating encapsulant 170. The conductive terminals 190 may be a ball grid array (BGA) formed by a ball placement process. The conductive terminals 190 may be disposed in the opening of the top layer of the patterned dielectric layer 184 to be in contact with the top layer of the patterned conductive layer 182 exposed by the patterned dielectric layer 184. A reflow process may be performed on the conductive terminals 190 to enhance the adhesion between the conductive terminals 190 and the patterned conductive layer 182. The conductive terminals 190 are in physical contact with the top layer of the patterned conductive layer 182 and electrically coupled to the semiconductor die 160 through the second redistribution structure 180. The conductive terminals 190 may take the form of pillars, balls, or posts, but other possible forms and shapes of the conductive terminals 190 may be utilized.

After the conductive terminals 190 are formed, the temporary carrier 110 may be removed to expose the semiconductor device 10 through a de-bonding process. External energy such as UV laser, visible light or heat, may be applied to the release layer 112 to peel off and separate the temporary carrier 110 from the semiconductor chip 120 and the insulator 130. Thereafter, a dicing or singulation process may be performed along a scribe line C to form a plurality of package-on-package (PoP) structures P1.

Referring to FIG. 1Q, the PoP structure P1 includes the semiconductor package 20 and the semiconductor device 10. The semiconductor package 20 may include the first redistribution structure 140 and the second redistribution structure 180, the semiconductor die 160, the conductive structure 152, the insulating encapsulant 170, and the conductive terminals 190. The first redistribution structure 140 includes the dielectric protrusion 148 encapsulated by the conductive structure 152. The dielectric protrusion 148 disposed on the second surface 140b vertically extends toward the conductive terminals 190. The dielectric protrusion 148 may serve as an anchor to reinforce the mechanical strength of the conductive structure 152. Hence, the conductive structure 152 is less prone to undergo deformation or other types of mechanical failures. Because the conductive structure 152 and the dielectric protrusion 148 can be fabricated with rather simple process steps, and because the increased mechanical resistance reduces the failure rate of the produced semiconductor packages, the overall yield of the process may be increased and manufacturing costs may be reduced. The conductive structure 152 formed in the peripheral region FOR electrically connects to the first redistribution structure 140 and the second redistribution structure 180 to achieve PoP structure. The conductive terminals 190 electrically coupled to the semiconductor die 160 provide further electrical connection between the PoP structure P1 and external electronic devices (not shown) such as a package substrate, a printed circuit board, etc.

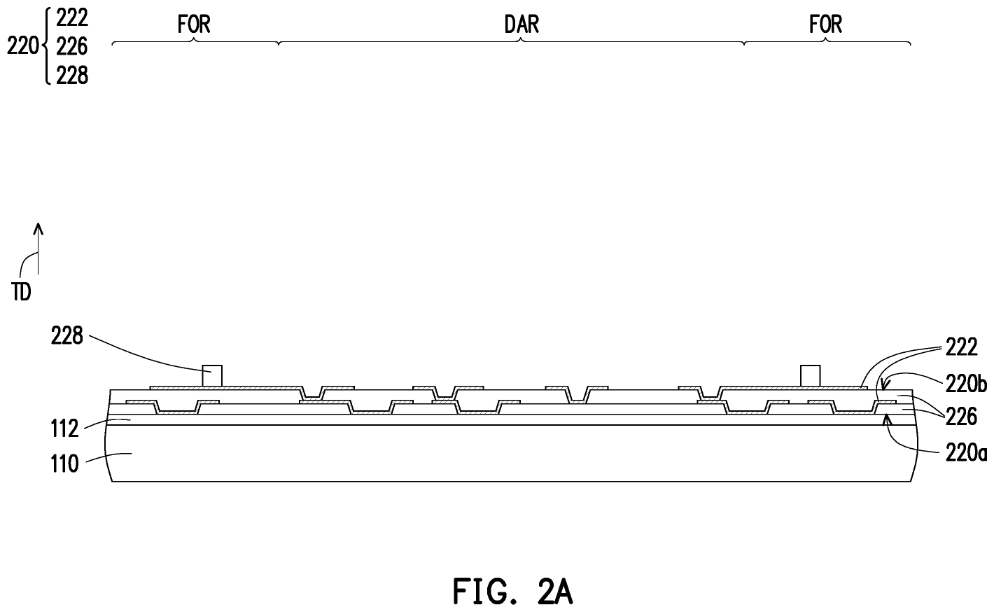

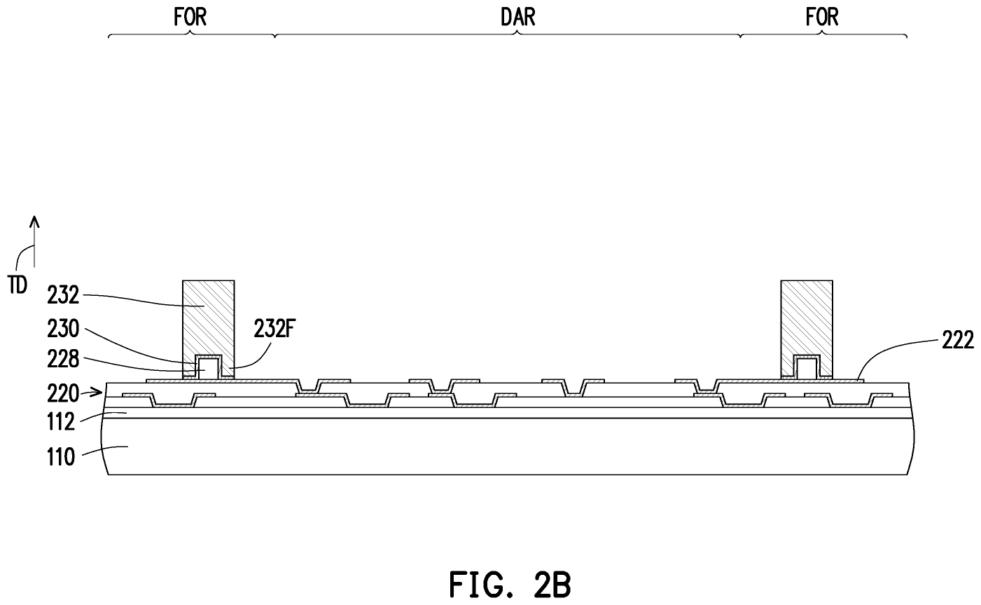

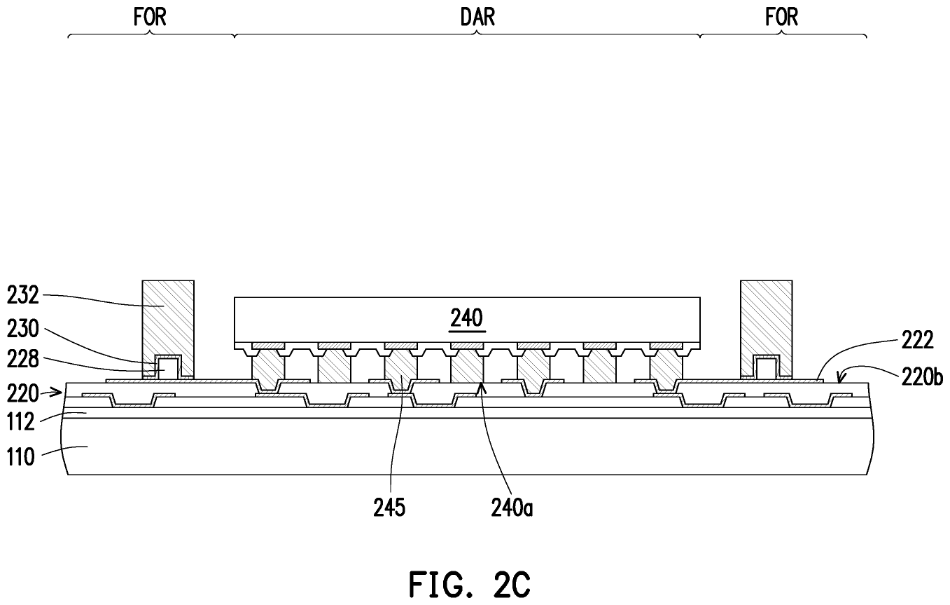

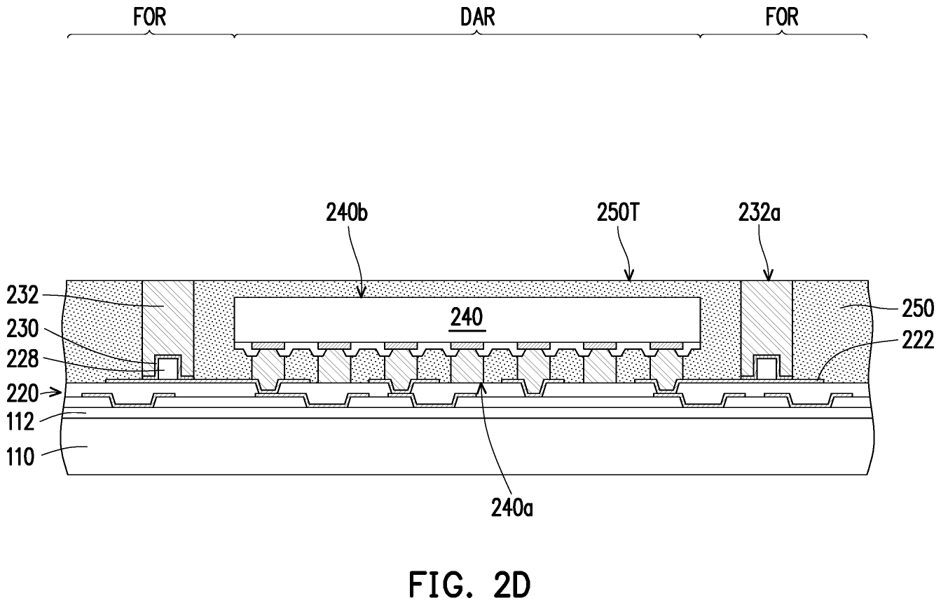

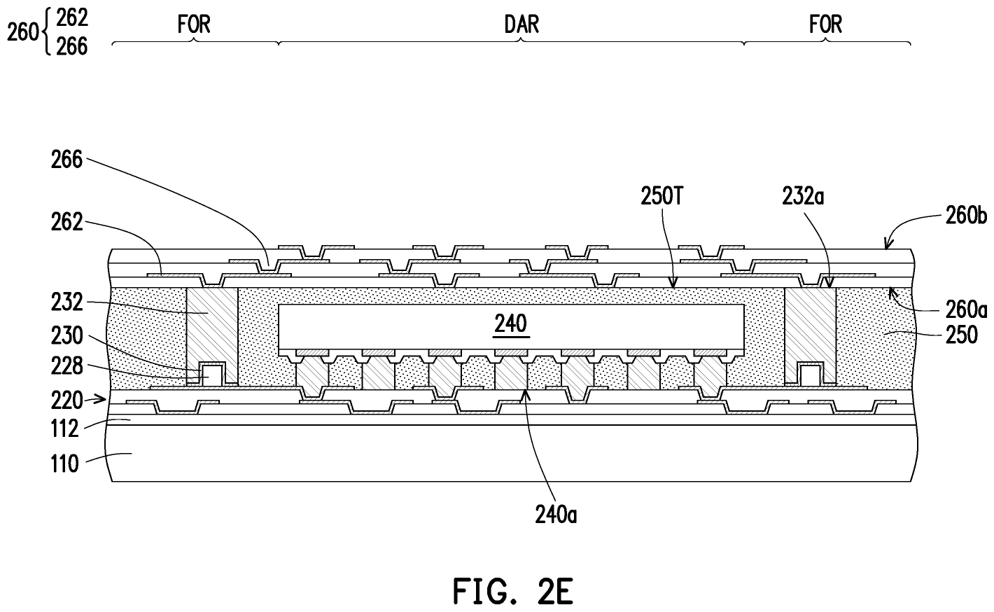

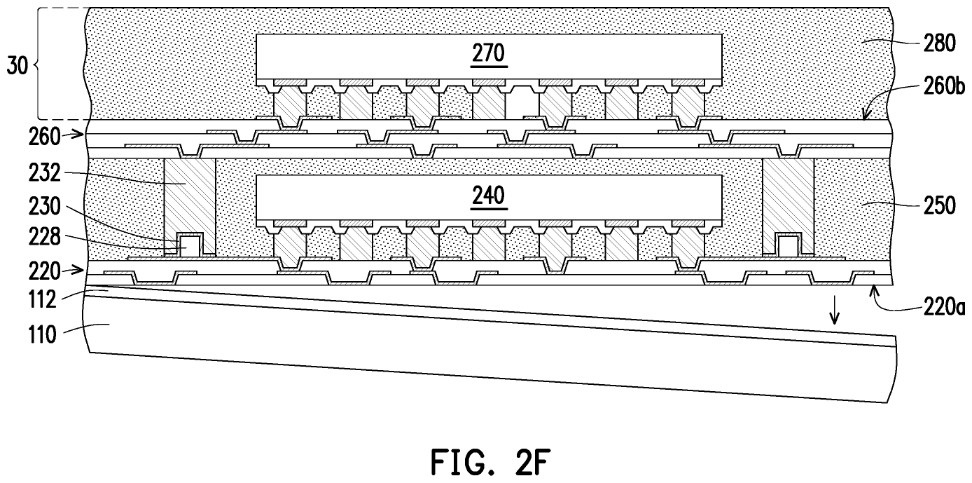

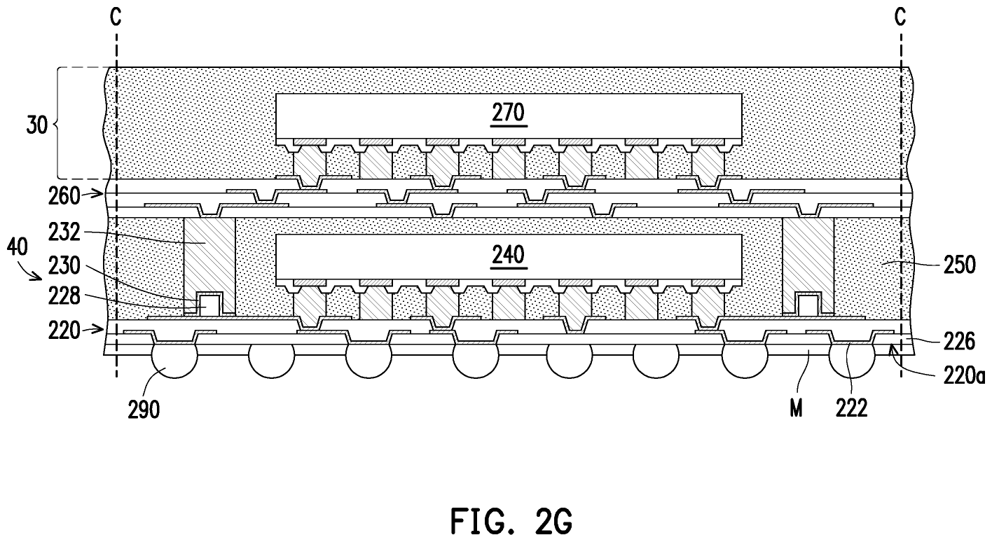

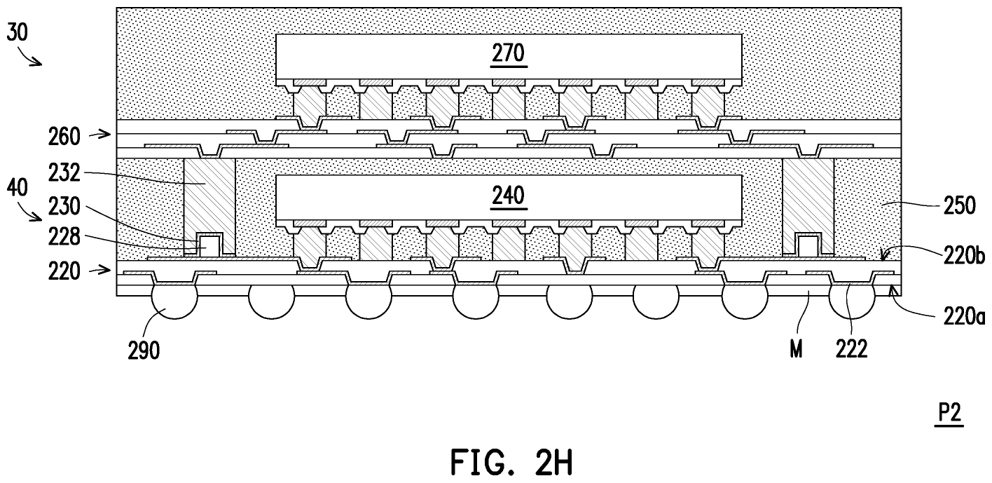

FIG. 2A to FIG. 2H are schematic cross-sectional views illustrating an application of a manufacturing method of a semiconductor package 40 according to some embodiments of the disclosure. Referring to FIG. 2A, the first redistribution structure 220 may be formed on the temporary carrier 110 with the release layer 112 optionally provided to increase the releasability of the temporary carrier 110 from the first redistribution structure 220. The first redistribution structure 220 may include at least one patterned conductive layers 222, at least one patterned dielectric layers 226, and the dielectric protrusion 228 disposed on the top patterned conductive layer 222. The first redistribution structure 220 has a first surface 220a and a second surface 220b opposite to the first surface 220a. The first surface 220a may face toward the temporary carrier 110 and the dielectric protrusion 228 may extend from the second surface 220b towards the thickness direction TD. The first redistribution structure 220 has the die attach region DAR and the peripheral region FOR surrounding the die attach region DAR. The dielectric protrusion 228 may be formed in the peripheral region FOR. The manufacturing process of the first redistribution structure 220 may be similar to that of the first redistribution structure 140. Thus, the detailed description is omitted for brevity.

In some other embodiments, a carrier substrate having a plurality of recesses (not shown) can be provided and the first redistribution structure may be formed on the carrier substrate. A dielectric material is first formed in the recesses of the carrier substrate to form the dielectric protrusion of the first redistribution structure such that the shape of the dielectric protrusion is complementary to the profile of each of the recesses. Next, a multi-layered first redistribution structure may be formed over the carrier substrate by forming the patterned conductive layer and the patterned dielectric layer alternately. A patterned conductive layer of the redistribution structure is formed over the carrier substrate, and at least a portion of the patterned conductive layer covers a surface the dielectric protrusion exposed through the carrier substrate. The patterned dielectric layer of the redistribution structure is formed over the patterned conductive layer, and the openings of the patterned dielectric layer expose at least a portion of the patterned conductive layer. In such embodiments, the openings of the patterned dielectric layer and the patterned conductive layer formed in the openings of the patterned dielectric layer extend in the same extending direction as the dielectric protrusion. After forming the first redistribution structure, the carrier substrate having the recesses can be separated from the first redistribution structure, and then the first redistribution structure can be flipped upside down and disposed on the temporary carrier 110 to perform the subsequent processes.

Referring to FIG. 2B, after forming the first redistribution structure 220, the conductive structure 232 may be formed on the dielectric protrusion 228 of the first redistribution structure 220 in the peripheral region FOR to electrically connect the top layer of the patterned conductive layer 222. The dielectric protrusion 228 extends in the thickness direction TD. The conductive structure 232 encapsulates the dielectric protrusion 228. The conductive structure 232 may include the footing portion 232F having a recess formed to substantially match the profile of the dielectric protrusion 228. A seed layer 230 may be formed before the conductive structure 232 to increase the adhesion of the conductive structure 232 and the first redistribution structure 220. The seed layer 230 may conformally cover the surface of the footing portion 232F of the conductive structure 232. The manufacturing process of the seed layer 230 and the conductive structure 232 may be similar to that of the seed layer 150 and the conductive structure 152, and the detailed description is omitted for brevity.

Referring to FIG. 2C, the semiconductor die 240 is disposed on the die attach region DAR of the first redistribution structure 220. The semiconductor die 240 may be similar to the semiconductor die 160. In some embodiments, the semiconductor die 240 may be disposed on the first redistribution structure 220 using a flip-chip technique. The top surfaces 240a of the conductive bumps 245 face toward the second surface 220b of the first redistribution structure 220. The conductive bumps 245 may be electrically connected to the patterned conductive layer 222 of the first redistribution structure 220. In other embodiments, after disposing the semiconductor die 240, an underfill (not illustrated) may be formed between the semiconductor die 240 and the second surface 220b of the first redistribution structure 220 to secure the connection between the semiconductor die 240 and the first redistribution structure 220.

Referring to FIG. 2D, the insulating encapsulant 250 is formed over the first redistribution structure 220 to encapsulate the semiconductor die 240 and the conductive structure 232. The insulating encapsulant 250 in the present embodiment may be formed with similar methods and materials as described for the insulating encapsulant 170. After forming the insulating encapsulant 250, the top surface 232a of the conductive structure 232 is exposed by the insulating encapsulant 250 and may be substantially coplanar with the top surface 250T of the insulating encapsulant 250. The thickness of the semiconductor die 240 may be less than the thickness of the insulating encapsulant 250, and the rear surface 240b of the semiconductor die 240 opposite to the top surfaces 240a may be covered by the insulating encapsulant 250. In some alternative embodiments, during the thinning process of the encapsulation material, a backside portion of the semiconductor die 240 may be removed such that the rear surface 240b of the semiconductor die 240 may be exposed by the insulating encapsulant 250 to further reduce the overall thickness of the semiconductor package 40. In certain embodiments, the rear surface 240b of the semiconductor die 240 and the top surface 232a of the conductive structure 232 may be substantially coplanar with the top surface 250T of the insulating encapsulant 250.

Referring to FIG. 2E, the second redistribution structure 260 is subsequently formed on the top surface 250T of the insulating encapsulant 250 and the top surface 232a of the conductive structure 232. The second redistribution structure 260 may include at least one patterned conductive layer 262 and at least one patterned dielectric layer 266. A portion of a bottom patterned conductive layer 262 exposed on a first surface 260a of the second redistribution structure 260 may be in contact with the top surface 232a of the conductive structure 232, thereby establishing the electrical connection with the conductive structure 232. Hence, the conductive structure 232 can provide vertical electrical connection within the semiconductor package 40 by electrically connecting the second redistribution structure 260 with the first redistribution structure 220. A portion of a top patterned conductive layer 262 is exposed on a second surface 260b opposite to the first surface 260a, and is available to form electrical connection with subsequently formed components. The second redistribution structure 260 may be formed with similar processes and materials as described for the second redistribution structure 180, and a detailed description thereof is omitted for brevity.

Referring to FIG. 2F, the semiconductor device 30 may be formed on the second surface 260b of the second redistribution structure 260 to electrically couple to the semiconductor die 240 through the second redistribution structure 260, the conductive structure 232 and the first redistribution structure 220. In some embodiments, the semiconductor device 30 may include the semiconductor chip 270 and the insulator 280 encapsulated the semiconductor chip 270. The semiconductor chip 270 may be attached onto the second redistribution structure 260 through a flip-chip technique, or other suitable techniques. In some embodiments, the top surface of the semiconductor chip 270 in the semiconductor device 30 may face toward the same direction with the top surfaces of the semiconductor die 240. In some alternative embodiments, the semiconductor chip 270 may be electrically coupled to the second redistribution structure 260 through a wire bonding process. After bonding the semiconductor chip 270, the insulator 280 may be formed over the second redistribution structure 260 to encapsulate the semiconductor chip 270 with similar methods and materials as described for the insulator 130 with reference to FIG. 1B, and a detailed description thereof is omitted for brevity. Thereafter, the semiconductor device 30 is formed. After forming the semiconductor device 30, the temporary carrier 110 may be removed to expose the first surface 220a of the first redistribution structure 220 through a de-bonding process with similar methods as described with reference to FIG. 1P.

Referring to FIG. 2G, after removal of the temporary carrier 110, the conductive terminals 290 may be formed on the first surface 220a of the first redistribution structure 220. The type or material of conductive terminals 290 in the present embodiment may be similar as that of the conductive terminals 190 described in FIG. 1P. In some embodiments, before forming the conductive terminals 290, a patterned mask layer M is optionally formed on the first surface 220a of the first redistribution structure 220. The patterned mask layer M has openings exposing at least a portion of the top patterned conductive layer 222 of the first redistribution structure 220. In some embodiments, the patterned mask layer M may be referred to as the solder mask or the solder resist for protecting the circuitry of the first redistribution structure 220 during the subsequent ball mounting process. In some alternative embodiments, a mask material layer may be first formed on the temporary 110 before forming the first redistribution structure 220, and after removal of the temporary carrier 110, the mask material layer may be patterned to form the patterned mask layer M. In other embodiments, the bottom patterned dielectric layer 226 of first redistribution structure 220 at the first surface 220a may include solder sensitive material covering the patterned conductive layer 222 for protection. In some embodiments, after forming the conductive terminals 290, a singulation process may be performed along the scribe line C to separate individual production intermediates to render a plurality of PoP structures P2.

Referring to FIG. 2H, the PoP structure P2 includes the semiconductor package 40 and the semiconductor device 30 stacked thereon. The semiconductor die 240 of the semiconductor package 40 is bonded to the first redistribution structure 220 using the flip-chip technique and thus no die attach layer required. The dielectric protrusion 228 of the semiconductor package 40 is disposed on the second surface 220b of the first redistribution structure 220 and vertically extends toward the semiconductor device 30. The conductive structure 232 may encapsulate the dielectric protrusion 228 to connect the first redistribution structure 220 with the second redistribution structure 260. The dielectric protrusion 228 may serve as an anchor to reinforce the mechanical strength of the conductive structure 232.

A semiconductor package according to some embodiments of the present disclosure is formed with a fan-out design suitable for vertical integration. Vertical electrical connection within the semiconductor package is provided by the conductive structure embedded in the insulating encapsulant. Since the conductive structure encapsulates a dielectric protrusion of the redistribution structure extending in a height direction of the conductive structure, the conductive structure is less prone to deformation or other types of mechanical failure. As the conductive structure and the dielectric protrusion may be formed by rather simple and cheap processes, and provide increased resistance to the produced semiconductor packages, the failure rate and the manufacturing cost of the semiconductor package may be significantly reduced.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor package, comprising:
a semiconductor die;
a first redistribution structure comprising a dielectric protrusion, wherein the first redistribution structure comprises a die attach region and a peripheral region surrounding the die attach region, the semiconductor die is disposed on the first redistribution structure within the die attach region, and the dielectric protrusion is disposed in the peripheral region and extends in a thickness direction of the semiconductor die;
a conductive structure disposed on the first redistribution structure within the peripheral region and encapsulating the dielectric protrusion, wherein the conductive structure is electrically coupled to the first redistribution structure and the semiconductor die; and
an insulating encapsulant disposed on the first redistribution structure and encapsulating the semiconductor die and the conductive structure.

2. The semiconductor package of claim 1, wherein the conductive structure comprises a recess complementary in shape to the dielectric protrusion entrenched therein.

3. The semiconductor package of claim 1, wherein a ratio between a height of the conductive structure and a height of the dielectric protrusion is in the range from 5 to 50.

4. The semiconductor package of claim 1, wherein a top surface of the insulating encapsulant is coplanar with a top surface of the conductive structure exposed by the insulating encapsulant.

5. The semiconductor package of claim 4, wherein the top surface of the insulating encapsulant is coplanar with a top surface of the semiconductor die, and a rear surface of the semiconductor die opposite to the top surface faces toward the first redistribution structure.

6. The semiconductor package of claim 1, further comprising:
a second redistribution structure disposed on the insulating encapsulant opposite to the first redistribution structure and electrically coupled to the semiconductor die and the conductive structure.

7. The semiconductor package of claim 1, further comprising:
a conductive terminal disposed on the second redistribution structure opposite to the insulating encapsulant and electrically connected to the second redistribution structure.

8. The semiconductor package of claim 1, further comprising:
a semiconductor device stacked on the semiconductor die and electrically coupled to the semiconductor die, the semiconductor device comprising a semiconductor chip and an insulator encapsulating the semiconductor chip.

9. The semiconductor package of claim 1, further comprising:
a seed layer disposed between the dielectric protrusion and the conductive structure and conformally covering the dielectric protrusion.

10. The semiconductor package of claim 1, wherein an orthogonal projection area of the dielectric protrusion on the first redistribution structure is located within an orthogonal projection area of the conductive structure on the first redistribution structure.

11. A manufacturing method of a semiconductor package, comprising:
forming a first redistribution structure, wherein the first redistribution structure comprises a die attach region, a peripheral region surrounding the die attach region, and a dielectric protrusion formed in the peripheral region and extending along a thickness direction of the first redistribution structure;
forming a conductive structure on the dielectric protrusion to encapsulate the dielectric protrusion, wherein the dielectric protrusion extends in a height direction of the conductive structure;
disposing a semiconductor die on the first redistribution structure within the die attach region to electrically couple to the first redistribution structure and the conductive structure; and
forming an insulating encapsulant on the first redistribution structure to encapsulate the conductive structure and the semiconductor die.

12. The manufacturing method of claim 11, wherein after forming the insulating encapsulant, at least a portion of the conductive structure is exposed by the insulating encapsulant, and the manufacturing method further comprises:
forming a second redistribution structure on the insulating encapsulant to electrically connect the conductive structure.

13. The manufacturing method of claim 11, further comprising:
providing a semiconductor device before forming the first redistribution structure or after forming the insulating encapsulant, wherein the semiconductor device is electrically coupled to the semiconductor die.

14. The manufacturing method of claim 11, wherein after forming the insulating encapsulant, a ratio between a height of the conductive structure and a height of the dielectric protrusion is in the range from 5 to 50.

15. The manufacturing method of claim 11, wherein after forming the insulating encapsulant, at least a portion of the conductive structure is exposed by the insulating encapsulant, and the manufacturing method further comprises:
forming a second redistribution structure on the insulating encapsulant, wherein the second redistribution structure is electrically connected to the conductive structure.

16. The manufacturing method of claim 15, further comprising:
forming a conductive terminal on the first redistribution structure or the second redistribution structure opposite to the insulating encapsulant.

17. The manufacturing method of claim 11, wherein forming the first redistribution structure comprises:
forming a patterned dielectric layer and a patterned conductive layer on the patterned dielectric layer; and
forming the dielectric protrusion on the patterned conductive layer.

18. The manufacturing method of claim 11, wherein after forming the conductive structure, the conductive structure has a recess complementary in shape to the dielectric protrusion entrenched therein.

19. The manufacturing method of claim 11, further comprising:
conformally forming a seed layer on the dielectric protrusion before forming the conductive structure.

20. The manufacturing method of claim 11, wherein the semiconductor die is provided with a die attach layer on a rear surface of the semiconductor die, and after disposing the semiconductor die, the rear surface of the semiconductor die is attached to the first redistribution structure through the die attach layer.
